(19) United States
(12) Patent Application Publication
(10) Pub. No.: US 2025/0120224 A1
(43) Pub. Date: Apr. 10, 2025

(54) OPTOELECTRONIC SEMICONDUCTOR DEVICE AND MANUFACTURING METHOD

(71) Applicant: AMS-OSRAM INTERNATIONAL GMBH, Regensburg (DE)

(72) Inventors: Anna Kasprzak-Zablocka, Donaustauf (DE); Tansen Varghese, Regensburg (DE)

(21) Appl. No.: 18/834,834

(22) PCT Filed: Feb. 2, 2023
(86) PCT No.: PCT/EP2023/052572

§ 371 Date: Jul. 31, 2024

(30) Foreign Application Priority Data
Feb. 10, 2022 (DE) 10 2022 103 158.6

(51) Int. Cl. H10H 20/84; H10H 20/01; H10H 20/824; H10H 29/01; H10H 29/14; H10H 29/85

(52) U.S. Cl. CPC H10H 20/84; H10H 20/017; H10H 20/824; H10H 29/011; H10H 29/034; H10H 29/142; H10H 29/857

(57) ABSTRACT

In an embodiment an optoelectronic semiconductor device includes a semiconductor layer sequence having an active region oriented perpendicular to a growth direction of the semiconductor layer sequence and a passivation regrowth layer oriented at least in part oblique to the active region, wherein the passivation regrowth layer is located directly on the semiconductor layer sequence and runs across a lateral boundary of the active region, wherein the semiconductor layer sequence and the passivation regrowth layer are based on the same semiconductor material system, and wherein the semiconductor material system is InGaAlP or AlInGaAsP.

### CROSS-REFERENCE TO RELATED APPLICATIONS

This patent application is a national phase filing under section 371 of PCT/EP2023/052572, filed Feb. 2, 2023, which claims the priority of German patent application 102022103158.6, filed Feb. 10, 2022, each of which is incorporated herein by reference in its entirety.

### TECHNICAL FIELD

An optoelectronic semiconductor device and a method for manufacturing such an optoelectronic semiconductor device are provided.

### SUMMARY

Embodiments provide an optoelectronic semiconductor device that can be manufactured with an increased yield.

According to at least one embodiment, the optoelectronic semiconductor device comprises a semiconductor layer sequence. The semiconductor layer sequence includes one or a plurality of active regions. The at least one active region is oriented perpendicular to a growth direction of the semiconductor layer sequence. The growth direction may be perpendicular to a main side of a growth substrate.

According to at least one embodiment, the semiconductor layer sequence is based on a III-V compound semiconductor material. The semiconductor material is for example a nitride compound semiconductor material such as AlₙIn₁₋ₙ₋ₘGaₘN or a phosphide compound semiconductor material such as AlₙIn₁₋ₙ₋ₘGaₘP or also an arsenide compound semiconductor material such as AlₙIn₁₋ₙ₋ₘGaₘAs, wherein in each case 0≤n≤1, 0≤m≤1 and n+m≤1 applies. The semiconductor layer sequence may comprise dopants and additional constituents. For simplicity's sake, however, only the essential constituents of the crystal lattice of the semiconductor layer sequence are indicated, i.e. Al, As, Ga, In, N or P, even if these may in part be replaced and/or supplemented by small quantities of further substances.

The semiconductor layer sequence is particularly preferably based on the AIInGaAsP material system and/or on the AlInGaP material system.

According to at least one embodiment, the optoelectronic semiconductor device comprises one or a plurality of passivation regrowth layers. The at least one passivation regrowth layer is oriented at least in part oblique to the active region. That is, the passivation regrowth layer at least in places does not run in parallel with the at least one active region. It is possible that the passivation regrowth layer at least in places or completely does not run in parallel with the growth direction.

According to at least one embodiment, the passivation regrowth layer is applied directly on the semiconductor layer sequence. Hence, the passivation regrowth layer and the semiconductor layer sequence touch each other. It is possible that the passivation regrowth layer is applied only on the semiconductor layer sequence so that the semiconductor layer sequence in each location of the passivation regrowth layer precedes the passivation regrowth layer, seen along the growth direction.

According to at least one embodiment, the passivation regrowth layer runs across a lateral boundary of the active region. That is, the lateral boundary is a lateral face of the active region, wherein the term ‘lateral’ refers to a direction perpendicular to the growth direction and/or to a direction of main extent of the active region. The passivation regrowth layer is preferably applied directly on the lateral boundary. Hence, the passivation regrowth layer directly touches the lateral boundary and, thus, the active region.

According to at least one embodiment, the semiconductor layer sequence and the passivation regrowth layer are based on the same semiconductor material system. For example, both the semiconductor layer sequence and the passivation regrowth layer are based on the AIInGaAsP material system or on the AlInGaP material system. Otherwise, the semiconductor layer sequence and the passivation regrowth layer may be based on the AIInGaN material system or also on the AlInGaAs material system.

In at least one embodiment, the optoelectronic semiconductor device comprises:
a semiconductor layer sequence including an active region oriented perpendicular to a growth direction of the semiconductor layer sequence, and
a passivation regrowth layer oriented at least in part oblique to the active region, wherein
the passivation regrowth layer is applied directly on the semiconductor layer sequence and runs across a lateral boundary of the active region, and
the semiconductor layer sequence and the passivation regrowth layer are based on the same semiconductor material system; for example, the semiconductor material system of the semiconductor layer sequence and the passivation regrowth layer is InGaAlP or AIInGaAsP, that is, AlₙIn₁₋ₙ₋ₘGaₘP or AlₙGaₘIn₁₋ₙ₋ₘAsₖP₁₋ₖ, wherein 0≤n≤1, 0≤m≤1, 0≤k≤1 and n+m≤1 applies.

In a possible process flow, the complete semiconductor layer sequence is grown and is then structured using a hard mask, for example, of SiO₂, and during structuring the active region is etched though until n-doped layers. Afterwards, a regrowth passivation is applied, and the hard mask is removed. The resulting pixel array is then ready for further processing, for example, for applying a transparent conductive oxide, like indium tin oxide, ITO for short, for electrical contacting, or for applying a mirror and the like.

However, in said process flow there can be problems with removing the SiO₂ hard mask. After etching of the hard mask, the pixel structure may partially be destroyed because the SiO₂ etchant also attacks the regrowth passivation.

In the optoelectronic semiconductor device described herein, one idea is to apply the passivation regrowth without a hard mask. Without the hard mask, there is no need to do any wet etching that possibly damages the passivation regrowth layer or the semiconductor layer sequence. The passivation regrowth layer is electrically insulating, so that in a next step the passivation regrowth layer can be opened to enable an electric contact to, for example, a GaP contact layer. Another advantage is that there is no need for an additional dielectric passivation layer.

According to at least one embodiment, the optoelectronic semiconductor device comprises a plurality of pixels. The pixels are configured to emit electromagnetic radiation. For example, said electromagnetic radiation is visible light like red light or yellow light, or said electromagnetic radiation is near-infrared radiation, in case of an AIJnGaAsP based semiconductor layer sequence. In case of an AIInGaN based semiconductor layer sequence, said electromagnetic radiation can also be blue light or green light or also near-ultraviolet radiation. Near-infrared radiation may refer to wavelengths between 700 nm and 1.5 μm and near-ultraviolet radiation may refer to wavelengths between 300 nm and 420 nm. The electromagnetic radiation is produced in the active region by electroluminescence.

According to at least one embodiment, each one of the pixels comprises a part of the semiconductor layer sequence and of the active region. In particular, all the pixels are made and structured from the same semiconductor layer sequence by means of etching. It is possible that the pixels share a common layer of the semiconductor layer sequence.

According to at least one embodiment, the pixels are applied on a common carrier. The common carrier can be a growth substrate of the semiconductor layer sequence or a substitute substrate that replaces a growth substrate. Likewise, the common carrier can be a circuit board or an electric carrier comprising conductor tracks and/or electric through-contacts and/or electric contact areas configured, for example, for soldering. It is possible that the semiconductor layer sequence extends in a continuous uninterrupted manner across the common carrier.

According to at least one embodiment, all the pixels are electrically contacted in parallel, for example, all the pixels can be turned on and off only collectively. Otherwise, groups of pixels or single pixels may individually be electrically addressed.

For example, the optoelectronic semiconductor device comprises at least 100 or at least 1000 of the pixels and/or comprises at most 10⁶ or at most 10⁵ or at most 10⁴ of the pixels.

According to at least one embodiment, the passivation regrowth layer extends in each case on a top side of the respective pixel. The top sides of the pixels are remote from the common carrier. In particular, the top sides are the sides of the pixels that limit the pixels along the growth direction. In other words, the top sides are the latest grown regions of the pixels.

According to at least one embodiment, seen in top view of the common carrier, a size of the pixels is at least 0.2 μm×0.2 μm or at least 0.8 μm×0.8 μm or at least 2 μm×2 m. Alternatively or additionally, said size of the pixels is at most 100 μm×100 μm or at most 10 μm×10 μm or at most 5 μm×5 μm or at most 3 μm×3 μm.

According to at least one embodiment, a height of the pixels above the common carrier or above a common semiconductor layer is at least 0.2 μm or at least 0.3 μm. Alternatively or additionally, said height is at most 10 μm or at most 3 μm or is at most 2 μm or is at most 1.1 μm.

According to at least one embodiment, seen in top view of the common carrier, a size of the optoelectronic semiconductor device is at least 20 μm×20 μm or at least 50 μm×50 μm or at least 100 μm×100 μm. Alternatively or additionally, said size of the optoelectronic semiconductor device is at most 30 mm×30 mm or at most 2 mm×2 mm or at most 0.3 mm×0.3 mm.

According to at least one embodiment, the common carrier is of a semiconductor material or comprises a semiconductor material. Said semiconductor material of the common carrier can be of the same semiconductor material system as the semiconductor layer sequence.

According to at least one embodiment, the passivation regrowth layer comprises one or a plurality of openings at each one of the top sides. Preferably, there is exactly one such opening per top side.

According to at least one embodiment, in each one of said openings and, thus, at each one of said top sides there is an electric contact layer. Preferably, the electric contact layer runs through the passivation regrowth layer and electrically contacts the respective top side and consequently the respective pixel.

According to at least one embodiment, the electric contact layer comprises at least one of a metallic mirror sub-layer and a contacting sub-layer. For example, the contacting sub-layer is of a transparent conductive oxide, like ITO. It is further possible that the electric contact layer comprises additional layers like a current spreading layer.

For example, the electric contact layer extends over all the pixels in a continuous uninterrupted manner. Otherwise, the electric contact layer may be a structured layer so that electric conductor tracks for individual pixels or groups of pixels may be present.

According to at least one embodiment, the passivation regrowth layer completely surrounds each one of the openings. Hence, the passivation regrowth layer can form a frame at the respective top sides.

According to at least one embodiment, a width of the respective frame on the respective top side is at least 0.1 μm or at least 0.2 μm or at least 1 μm. Alternatively or additionally, said width is at most 5 μm or is at most 0.9 μm or is at most 0.3 μm or is at most 0.2 μm. Alternatively or additionally, said width is at least 5% or at least 10% or at least 20% of an extent of the respective pixel, in particular seen along a same direction perpendicular to the growth direction. Optionally, said width is at most 40% or at most 30% or at most 20% of said extent.

According to at least one embodiment, the passivation regrowth layer completely covers lateral faces of the pixels. In other words, the lateral faces of the pixels are completely protected and electrically insulated by the passivation regrowth layer.

According to at least one embodiment, the passivation regrowth layer extends as a continuous layer across all the pixels. Beside the openings at the top sides, the passivation regrowth layer can be an uninterrupted, closed layer.

According to at least one embodiment, the semiconductor material system of the semiconductor layer sequence and of the passivation regrowth layer is InGaAlP. If there is a growth substrate as the common carrier, the common carrier can be of the GaAs material system.

According to at least one embodiment, a thickness of the passivation regrowth layer is at least 50 nm or is at least 100 nm or is at least 150 nm. Alternatively or additionally, said thickness is at most 1 μm is at most 0.5 μm or is at most 0.3 μm.

According to at least one embodiment, the thickness of the passivation regrowth layer is constant across the optoelectronic semiconductor device, for example, with a tolerance of at most 50% or of at most 20% or of at most 10% of a mean thickness of the passivation regrowth layer. Hence, the passivation regrowth layer can be free of intended thickness variations.

According to at least one embodiment, the passivation regrowth layer is of single-layer fashion. Thus, the passivation regrowth layer can be made of a single material homogeneously distributed all across the passivation regrowth layer.

According to at least one embodiment, the passivation regrowth layer is of multi-layer fashion. Hence, the passivation regrowth layer comprises two or at least three sub-layers. Adjacent sub-layers or all the sub-layers differ from each other in a material composition concerning main constituents of a crystal lattice of the semiconductor material system. Alternatively or additionally, adjacent sub-layers or all the sub-layers differ from each other in a doping concentration and/or in a doping type. Doping type refers to n-doped or p-doped or not doped. Not doped may mean a concentration of non-main constituents of the crystal lattice of at most 5×10¹⁶ cm⁻³.

According to at least one embodiment, the semiconductor layer sequence comprises all or some of the following layers in the stated sequence, in particular seen along the growth direction:
a first buffer layer, which is, for example, n-doped,
an first contact layer, which is, for example, n-doped,
a first barrier layer, which is, for example, n-doped or not doped,
a first cladding layer, which is, for example, n-doped or not doped,
the active region, which comprises, for example, a single-quantum well structure or a multiple-quantum well structure, so that the active region could comprise at least one quantum well and at least one adjoining active region barrier layer,
a second cladding layer, which is, for example, p-doped or not doped,
a second barrier layer, which is, for example, p-doped or not doped,
a second buffer layer, which is, for example, p-doped, and
a second contact layer, which is, for example, p-doped or not doped.

According to at least one embodiment, at least the first contact layer, the first barrier layer, the first cladding layer, the active region, the second cladding layer, the second barrier layer, the second buffer layer, and the second contact layer are in direct contact with the passivation regrowth layer. For example, in regions adjacent to the pixels the first cladding layer, the active region, the second cladding layer, the second barrier layer, the second buffer layer, and the second contact layer can be completely removed. The first contact layer and/or the first barrier layer can be completely or partially removed.

According to at least one embodiment, the optoelectronic semiconductor device is a micro-LED or comprises a micro-LED. As a broad definition, a micro-LED could be seen as any light emitting diode, LED, generally not a laser, with a particularly small size. For example, a growth substrate is removed from micro-LEDs, so that typical heights of such micro-LEDs are in the range of 1.5 μm to 10 μm, for example.

In principle, a micro-LED does not necessarily have to have a rectangular radiation emission surface. Generally, for example, an LED could have a radiation emission surface in which, in plan view of the layers of the layer stack, any lateral extent of the radiation emission surface is less than or equal to 100 μm or less than or equal to 70 μm. For example, in the case of rectangular micro-LEDs, an edge length, especially in plan view of the layers of the layer stack, smaller than or equal to 70 μm or smaller than or equal to 50 μm may be a criterion. Mostly, such micro-LEDs are provided on wafers with—for the μLED non-destructively—detachable holding structures.

At present, micro-LEDs are mainly used in displays. The micro-LEDs form pixels or subpixels and emit light of a defined color. Small pixel size and a high density with close distances make micro-LEDs suitable, among others, for small monolithic displays for augmented reality, AR, applications, especially data glasses. In addition, other applications are being developed, in particular regarding the use in data communication or pixelated lighting applications.

Different ways of spelling micro-LED, like μLED, μ-LED, μLED, μ-LED or micro light emitting diode can be found in the relevant literature.

A method for manufacturing the optoelectronic semiconductor device is additionally provided. By means of the method, an optoelectronic semiconductor device is produced as indicated in connection with at least one of the above-stated embodiments. Features of the optoelectronic semiconductor device are therefore also disclosed for the method and vice versa.

In at least one embodiment, the manufacturing method is for producing the optoelectronic semiconductor device which comprises the pixels. The method comprises the following steps, preferably in the stated order:
A) providing the semiconductor layer sequence,
B) etching the semiconductor layer sequence so that the pixels are formed, the etching is through the active region so that the lateral boundaries of the parts of the active region are formed, and
C) applying the passivation regrowth layer directly on the semiconductor layer sequence including at least the lateral boundaries of the parts of the active region.

### BRIEF DESCRIPTION OF THE DRAWINGS

An optoelectronic semiconductor device and a method described herein are explained in greater detail below by way of exemplary embodiments with reference to the drawings. Elements which are the same in the individual figures are indicated with the same reference numerals. The relationships between the elements are not shown to scale, however, but rather individual elements may be shown exaggeratedly large to assist in understanding.

FIGS. 1 to 4 are schematic sectional views along a growth direction of method steps to produce a semiconductor device;

FIG. 5 is a schematic sectional views along a growth direction of an exemplary embodiment of an optoelectronic semiconductor device described herein;

FIGS. 6 and 7 are schematic top views of exemplary embodiments of optoelectronic semiconductor devices described herein;

FIGS. 8 to 13 are schematic sectional views along a growth direction of method steps of an exemplary embodiment of a manufacturing method for optoelectronic semiconductor devices described herein; and

FIG. 14 is a schematic sectional view of an exemplary embodiment of an optoelectronic semiconductor device described herein.

### DETAILED DESCRIPTION OF ILLUSTRATIVE EMBODIMENTS

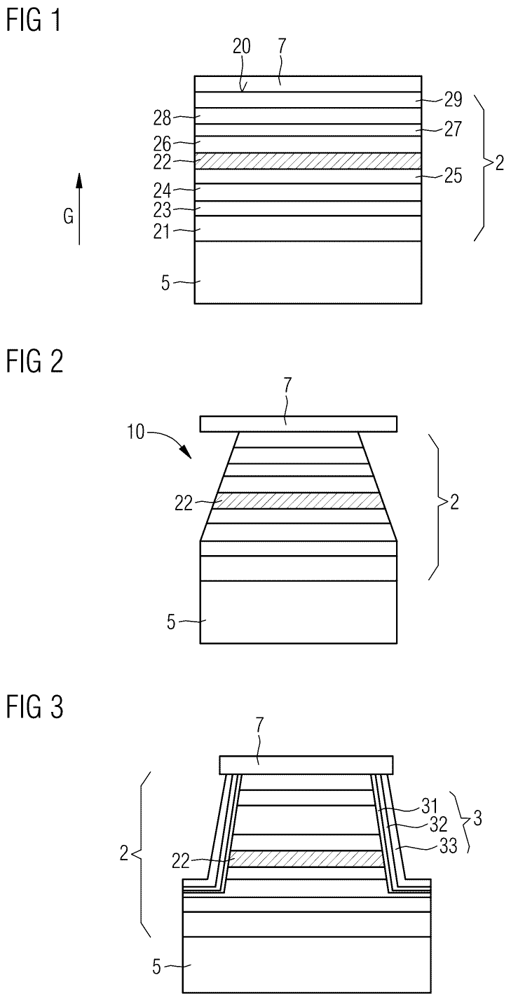

FIGS. 1 to 4 illustrate a variant of a method for producing a modified semiconductor device 9.

According to FIG. 1, a semiconductor layer sequence 2 is grown on a common carrier 5. The semiconductor layer sequence 2 is based on AlInGaP and comprises an active region 22 to produce, for example, red light. Further, the semiconductor layer sequence 2 may comprise additional layers 21, 23, 24, 25, 26, 27, 28, 29 following each other along a growth direction G.

The semiconductor layer sequence 2 terminates with a top side 20 remote from the common carrier 5. On the top side 20, a mask layer 7 is applied. For example, the mask layer 7 is a hard mask made of, for example, SiO₂.

Subsequently, see FIG. 2, the semiconductor layer sequence 2 is etched based on the structured mask layer 7 so that a plurality of pixels 10 result. The pixels 10 may have inclined side faces. The mask layer 7 is partially undercut. For simplifying the drawing, only one of the pixels 10 is illustrated.

Then, see FIG. 3, a passivation regrowth layer 3 is grown on areas of the semiconductor layer sequence 2 not covered by the mask layer 7. Because the mask layer 7 is still present, the top side 20 is free of the passivation regrowth layer 3. The passivation regrowth layer 3 can be composed of sub-layers 31, 32, 33.

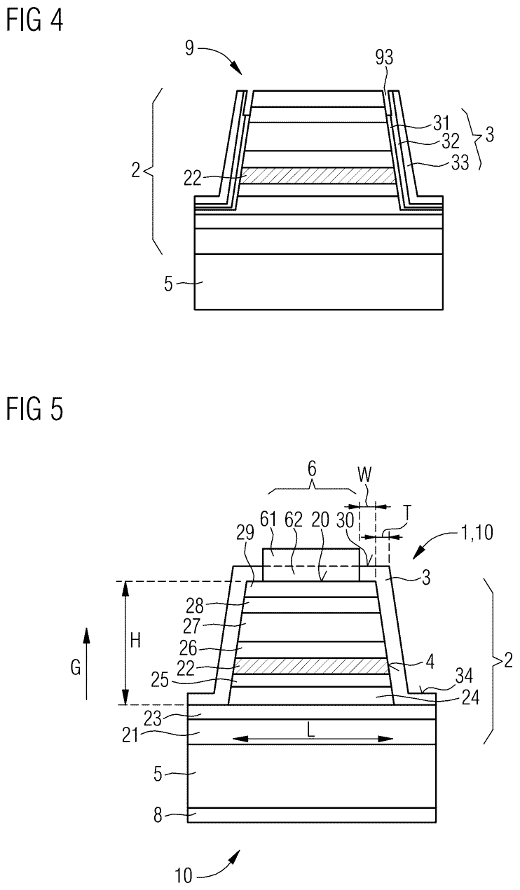

Afterwards, see FIG. 4, the mask layer 7 is removed, for example, by means of wet etching. However, this etching can also attack the passivation regrowth layer 3, or at least one of its sub-layers 31. Hence, a damage 93 may result that can reduce manufacturing yield and/or efficiency of the modified semiconductor device 9.

To overcome the possible negative effects of removing the mask layer 7 as explained in connection with FIG. 4, an optoelectronic semiconductor device 1 described herein comprises a different passivation regrowth layer 3 so that damages 93 can be avoided.

According to FIG. 5, the optoelectronic semiconductor device 1 comprises the passivation regrowth layer 3 which extends onto the top side 20 of the pixel 10. Preferably, the optoelectronic semiconductor device 1 includes a plurality of the pixels 10 while only one pixel 10 is illustrated in FIG. 5.

Thus, the passivation regrowth layer 3 has the shape of a frame at the top side 20. A width W of the frame and, thus, of the passivation regrowth layer 3 around the top side 20 is, for example, between 0.3 μm and 1.0 μm. A thickness T of the passivation regrowth layer 3 is, for example, between 100 nm and 500 nm. It is possible that the passivation regrowth layer 3 is a single, homogeneous layer. For example, the passivation regrowth layer 3 is of undoped InAlP or of undoped InGaAlP. A top side 30 of the passivation regrowth layer 3 can thus be more distant from the active region 22 than the top side 20 of the semiconductor layer sequence 2, unlike in FIGS. 3 and 4.

At the top side 20, the passivation regrowth layer 3 has an opening. In this opening, there is preferably an electric contact layer 6. It is possible that the electric contact layer 6 is limited to the opening or partially or completely covers the passivation regrowth layer 3, other than shown in FIG. 5. As an option, the electric contact layer 6 comprises a contacting sub-layer 62 directly at the top side 20 which is, for example, of a transparent conductive oxide like ITO or ZnO. As a further option, the electric contact layer 6 can comprise a mirror sub-layer 61 which is, for example, a metallic layer in particular of Ag. The electric contact layer 6 can protrude the opening and can thus be thicker than the passivation regrowth layer 3.

An edge length of the pixel 10 is, for example, between 0.5 μm and 10 μm inclusive, but could also be as large as 100 μm. The pixel 10 can be a light-emitting diode, LED for short, and because its small lateral dimensions the pixel can be referred to as a PLED.

For example, the common carrier 5 is a growth substrate for the semiconductor layer sequence 2. The semiconductor layer sequence 2 is based on the AIInGaAsP material system, for example. In this case, the common carrier 5 can be a GaAs growth substrate.

The semiconductor layer sequence 2 includes, for example, a first buffer layer 21 in particular directly at the common carrier 5. The first buffer layer 21 can be an n-doped AlGaAs layer.

Optionally, the first buffer layer 21 is followed by a first contact layer 23. For example, the first contact layer 23 is an n-doped layer made of InGaAlP.

Then, there can be a first barrier layer 24. The first barrier layer 24 is, for example, made of undoped InAlP.

It is possible that the first barrier layer 24 is followed by a first cladding layer 25. For example, the first cladding layer 25 is made of undoped InGaAlP.

Then, there is the active region 22 based on, for example, undoped InGaAlP. In the active region 22, electromagnetic radiation is produced in operation of the optoelectronic semiconductor device 1. At side faces of the pixel 10, there is a lateral boundary 4 of the active region 22. The lateral boundary 4 as well as the remaining parts of the side faces are completely covered by the passivation regrowth layer 3 which is of approximately constant thickness.

On a side of the active region 22 facing away from the common carrier 5, there can be a second cladding layer 26 which is, for example, of undoped InGaAlP.

Optionally, the second cladding layer 26 is followed by a second barrier layer 27. The second barrier layer 27 can be made of μ-doped InAlP.

As a further option, the second barrier layer 27 is followed by a second buffer layer 28. The second buffer layer 28 is, for example, a μ-doped InGaAlP layer.

Finally, next to the top side 20, the semiconductor layer sequence 2 can be finished with a second contact layer 29 which is, for example, a GaP layer.

The semiconductor layer sequence 2 of FIG. 5 is etched down to the first contact layer 23. Hence, the first contact layer 23 can be unaffected or essentially unaffected by etching the pixels 10, and can be a continuous layer on the common carrier 5 together with the first buffer layer 21. Otherwise, it is alternatively possible that the first contact layer 23 and optionally also the first buffer layer 21 are removed so that by the etching the common carrier 5 may be exposed in places.

A height H of the pixels 10 above the last continuous layer, that is, according to FIG. 5 the first contact layer 23, is preferably at least 0.2 μm and/or at most 1.0 μm, for example, if the length L is about 1 μm.

As a further option, there can be a bottom side electric contact 8. The bottom side electric contact 8 is applied, for example, on a side of the common carrier 5 remote from the semiconductor layer sequence 2. Other than shown, the bottom side electric contact 8 can also be applied on a side of the first contact layer 23 remote from the common carrier 5.

Otherwise, the same as to FIGS. 1 to 4 may also apply to FIG. 5, and vice versa.

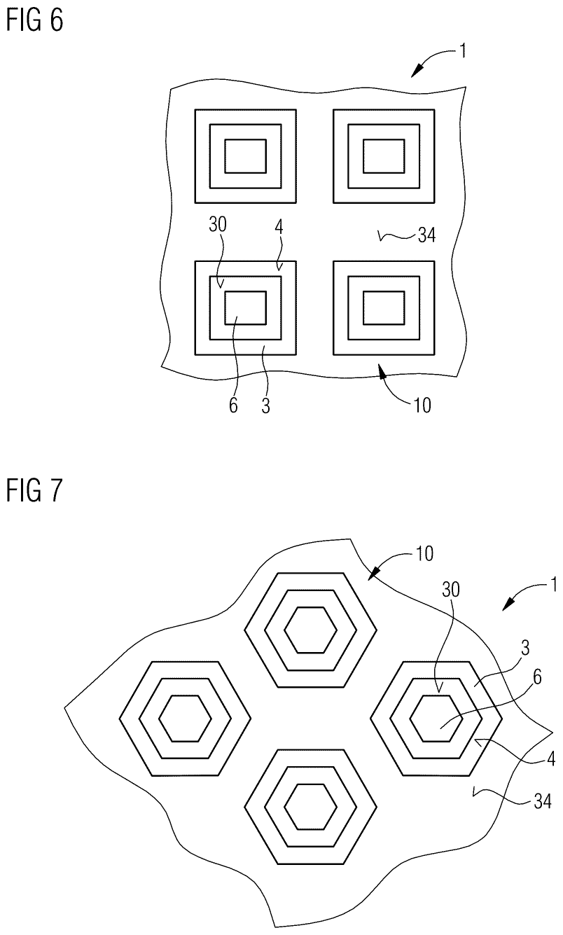

In FIGS. 6 and 7, top views of optoelectronic semiconductor devices 1 are shown. The optoelectronic semiconductor devices 1 can be configured in cross-section as explained in connection with FIG. 5.

According to FIG. 6, the pixels 10 are arranged in a regular, rectangular grid. Seen in top view, the pixels 10 are of square or rectangular shape so that the pixels 10 can be shaped as truncated pyramids.

According to FIG. 7, the pixels 10 are arranged in a hexagonal grid. The pixels 10 can thus be shaped as hexagons, seen in top view, or also as rectangles or squares.

Other than shown in FIGS. 6 and 7, the pixels 10 can also be of round, in particular of circular shape, seen in top view.

It is possible that all the pixels 10 are of the same design. Otherwise, differently shaped or grown pixels 10 can be combined with each other. The pixels 10 can be contacted electrically in parallel, or groups of pixels 10 or individual pixels 10 can be electrically addressed independent of one another.

The optoelectronic semiconductor device 1 is, for example, a device for displays or can serve as a light source in applications like augmented and/or virtual reality, for example, in corresponding goggles.

Otherwise, the same as to FIGS. 1 to 5 may also apply to FIGS. 6 and 7, and vice versa.

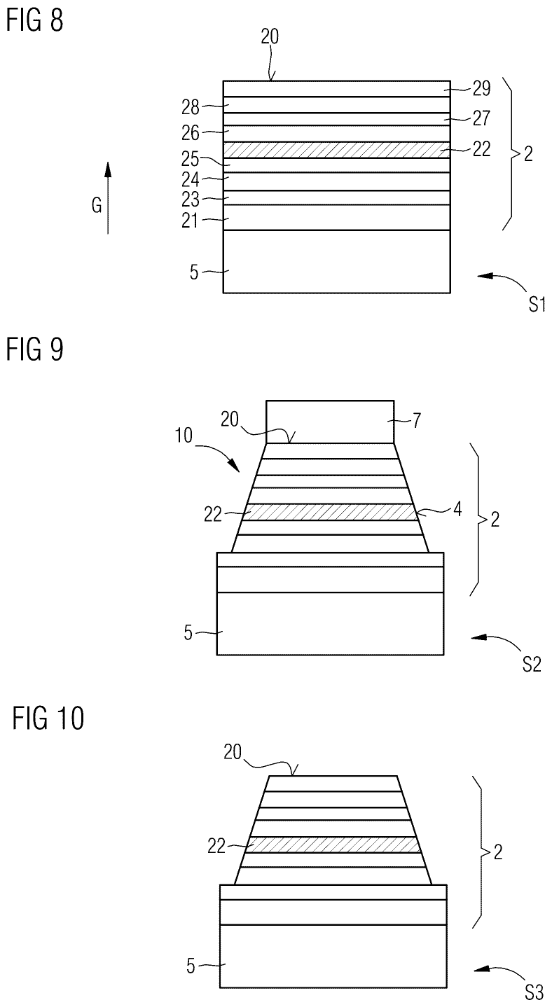

In FIGS. 8 to 13, a manufacturing method for optoelectronic semiconductor devices 1 is illustrated.

According to FIG. 8, in a method step S1 the semiconductor layer sequence 2 is grown along the growth direction G starting from the common carrier 5. The semiconductor layer sequence 2 can be configured as described in connection with FIG. 5.

In method step S2, see FIG. 9, the mask layer 7 is applied. For example, the mask layer 7 is made of a photo resist or of a metal oxide like Al₂O₃. The mask layer 7 can be made of a dry or of a wet resist. Then, the semiconductor layer sequence 2 is etched to form the individual pixels 10. Again, only one of the pixels 10 is illustrated while there is preferably a plurality of the pixels 10 which are spaced apart from one another.

The etching may be down to the first contact layer 23, for example. By means of the etching, the oblique side faces of the pixels 10 including the lateral boundary 4 are formed. Seen in cross-section, on top of the continuous first contact layer 23 the pixels 10 may have the shape of symmetric trapezoids.

In subsequent method step S3, see FIG. 10, the mask layer 7 is removed. Because the mask layer 7 is of an easy to remove material like a resist, the previously etched pixels 10 are not affected by removal of the mask layer 7.

Then, in method step S4 as illustrated in FIG. 11, the passivation regrowth layer 3 is grown. Thus, the passivation regrowth layer 3 preferably completely covers the side faces and the top side 20 of the pixels 10. The passivation regrowth layer 3 can be made of an undoped InAlP or undoped InGaAlP layer.

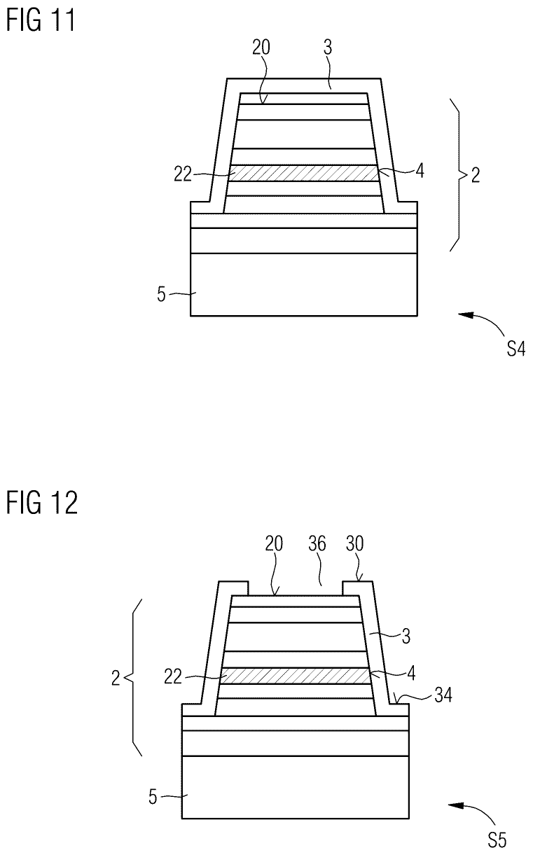

In method step S5, see FIG. 12, the openings are formed in the passivation regrowth layer 3 on top of each one of the pixels 10. Accordingly, the top sides 20 of the pixels 10 are partially exposed. The frames of the passivation regrowth layer 3 preferably remain at edges of the top sides 20.

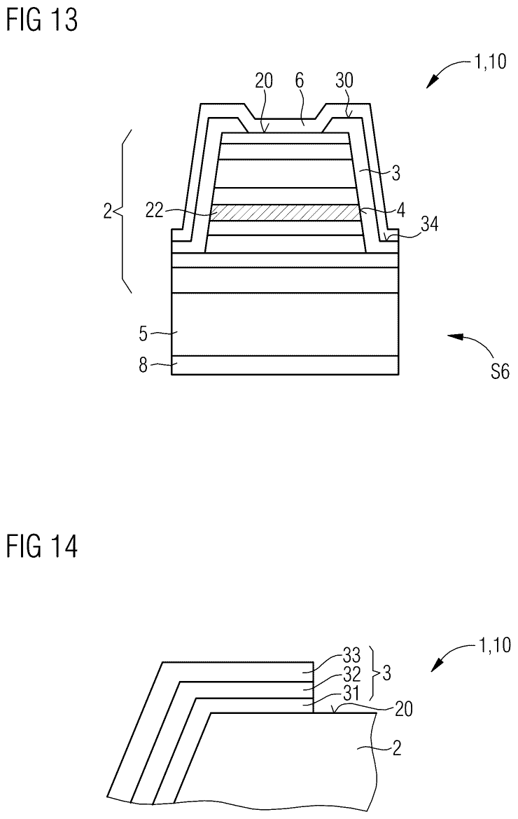

Finally, the method step S6 of FIG. 13, the electric contact layer 6 is applied. For example, the electric contact layer 6 is an ITO layer or comprises an ITO layer. Further layers, not shown, like a mirror layer, a barrier layer and/or a current spreading layer can also be present in the electric contact layer 6. For example, a thickness of the electric contact layer 6 is at least 50 nm and/or at most 0.5 μm. The electric contact layer 6 can be of approximately constant layer thickness and may copy a contour of the passivation regrowth layer 3.

Otherwise, the same as to FIGS. 1 to 7 may also apply to FIGS. 8 to 13, and vice versa.

In FIG. 14 it is illustrated that the passivation regrowth layer 3 is composed of, for example, three sub-layers 31, 32, 33. The sub-layers 31, 32, 33 differ from each other in their doping type and/or material composition. For example, μ-doped, n-doped and not doped sub-layers 31, 32, 33 can be combined with each other.

For example, the innermost sub-layer 31 is of undoped InAlP, followed by the middle sub-layer 32 of μ-doped InAlP and the topmost sub-layer 33 is of n-doped InAlP. There can be more than three of the sub-layers. If the semiconductor layer sequence 2 is of the AIInGaN material system, the passivation regrowth layer 3 can be, for example, of undoped and differently doped layers of AlGaN.

Such a passivation regrowth layer 3 can be used in all other examples, too.

Otherwise, the same as to FIGS. 1 to 13 may also apply to FIG. 14, and vice versa.

The components shown in the figures follow, unless indicated otherwise, exemplarily in the specified sequence directly one on top of the other. Components which are not in contact in the figures are exemplarily spaced apart from one another. If lines are drawn parallel to one another, the corresponding surfaces may be oriented in parallel with one another. Likewise, unless indicated otherwise, the positions of the drawn components relative to one another are correctly reproduced in the figures.

The invention described here is not restricted by the description on the basis of the exemplary embodiments. Rather, the invention encompasses any new feature and also any combination of features, which includes in particular any combination of features in the patent claims, even if this feature or this combination itself is not explicitly specified in the patent claims or exemplary embodiments.

1-15. (canceled)

16. An optoelectronic semiconductor device comprising:
a semiconductor layer sequence comprising an active region oriented perpendicular to a growth direction of the semiconductor layer sequence; and
a passivation regrowth layer oriented at least in part oblique to the active region,
wherein the passivation regrowth layer is located directly on the semiconductor layer sequence and runs across a lateral boundary of the active region,
wherein the semiconductor layer sequence and the passivation regrowth layer are based on the same semiconductor material system, and
wherein the semiconductor material system is InGaAlP or AIInGaAsP.

17. The optoelectronic semiconductor device according to claim 16, further comprising:
a plurality of pixels configured to emit electromagnetic radiation produced in the active region by electroluminescence,
wherein each one of the pixels comprises a part of the semiconductor layer sequence and of the active region,
wherein the pixels are arranged on a common carrier,
wherein the passivation regrowth layer extends in each case on a top side of a respective pixel, and
wherein the top sides are remote from the common carrier.

18. The optoelectronic semiconductor device according to claim 17,
wherein, seen in top view of the common carrier, a size of each pixel is at least 0.2 μm×0.2 μm and at most 100 μm×100 μm, and a height of the pixels above the common carrier is at least 0.2 μm and at most 2 μm, and
wherein the optoelectronic semiconductor device is a micro-LED.

19. The optoelectronic semiconductor device according to claim 17, wherein the common carrier is of a semiconductor material and is a common growth substrate for all the pixels.

20. The optoelectronic semiconductor device according to claim 17, wherein the passivation regrowth layer comprises an opening at each one of the top sides, and wherein in each one of the openings an electric contact layer runs through the passivation regrowth layer and electrically contacts the respective pixel.

21. The optoelectronic semiconductor device according to claim 20, wherein the electric contact layer comprises at least one of a metallic mirror sub-layer and a contacting sub-layer of a transparent conductive oxide.

22. The optoelectronic semiconductor device according to claim 20, wherein the passivation regrowth layer completely surrounds each one of the openings as a frame at the respective top side, the wherein a width of the respective frame on the respective top side is at least 0.1 μm and at most 5 μm and/or is at least 5% and at most 30% of an extent of the respective pixel seen along the same direction perpendicular to the growth direction.

23. The optoelectronic semiconductor device according to claim 17, wherein the passivation regrowth layer extends as a continuous layer across all the pixels and completely covers lateral faces of the pixels.

24. The optoelectronic semiconductor device according to claim 16, wherein the semiconductor material system is InGaAlP.

25. The optoelectronic semiconductor device according to claim 16, wherein a thickness of the passivation regrowth layer is at least 50 nm and is at most 0.5 μm.

26. The optoelectronic semiconductor device according to claim 25, wherein the thickness is constant across the optoelectronic semiconductor device with a tolerance of at most 50% of a mean thickness of the passivation regrowth layer.

27. The optoelectronic semiconductor device according to claim 16, wherein the passivation regrowth layer is a single layer.

28. The optoelectronic semiconductor device according to claim 16, wherein the passivation regrowth layer is a multi-layer and comprises at least two sub-layers, wherein the at least two sub-layers differ from each other in at least one of a material composition concerning main constituents of a crystal lattice of the semiconductor material system and a doping concentration.

29. The optoelectronic semiconductor device according to claim 16,
wherein the semiconductor layer sequence comprises in the stated sequence:
a first buffer layer,
an n-doped contact layer,
a first barrier layer,
a first cladding layer,
the active region,
a second cladding layer,
a second barrier layer,
a second buffer layer, and
a p-doped contact layer, and
wherein at least the first cladding layer, the active region, the second cladding layer, the second barrier layer, the second buffer layer, and the μ-doped contact layer are in direct contact with the passivation regrowth layer.

30. The optoelectronic semiconductor device according to claim 16, wherein a material of the common carrier is of a GaAs material system.

16. The optoelectronic semiconductor device according to claim 16,
wherein the common carrier is a substitute substrate that replaces a growth substrate, and
wherein the common carrier is a circuit board or an electric carrier comprising conductor tracks and/or electric through-contacts and/or electric contact areas.

32. A manufacturing method for producing the optoelectronic semiconductor device according to claim 16, the method comprising:
providing the semiconductor layer sequence;
etching the semiconductor layer sequence so that pixels are formed, wherein etching comprises etching through the active region so that the lateral boundaries of parts of the active region are formed; and
applying the passivation regrowth layer directly on the semiconductor layer sequence including the lateral boundaries.

33. An optoelectronic semiconductor device comprising:
a semiconductor layer sequence including an active region oriented perpendicular to a growth direction of the semiconductor layer sequence;
a passivation regrowth layer oriented at least in part oblique to the active region; and
a plurality of pixels configured to emit electromagnetic radiation produced in the active region by electroluminescence so that there are at least 100 of the pixels,
wherein the passivation regrowth layer is directly located on the semiconductor layer sequence and runs across a lateral boundary of the active region,
wherein the semiconductor layer sequence and the passivation regrowth layer are based on the same semiconductor material system,
wherein the semiconductor material system is InGaAlP or AIInGaAsP,
wherein each one of the pixels comprises a part of the semiconductor layer sequence and of the active region,
wherein the pixels are arranged on a common carrier,
wherein the passivation regrowth layer extends in each case on a top side of a respective pixel,
wherein the top sides are remote from the common carrier,
wherein the passivation regrowth layer comprises an opening at each one of the top sides, and
wherein in each one of the openings an electric contact layer runs through the passivation regrowth layer and electrically contacts the respective pixel.
